(19) United States
(12) Patent Application Publication
(10) Pub. No.: US 2025/0357133 A1
(43) Pub. Date: Nov. 20, 2025

(54) ETCHING METHOD AND PLASMA PROCESSING APPARATUS

(71) Applicant: Tokyo Electron Limited, Tokyo (JP)

(72) Inventors: Takahiro TAKEUCHI, Hillsboro, OR (US); Masahiko TAKAHASHI, Miyagi (JP)

(73) Assignee: Tokyo Electron Limited, Tokyo (JP)

(21) Appl. No.: 19/287,880

(22) Filed: Aug. 1, 2025

Related U.S. Application Data
(63) Continuation of application No. PCT/JP2024/002876, filed on Jan. 30, 2024.

(30) Foreign Application Priority Data
Feb. 13, 2023 (JP) 2023-019757

(51) Int. Cl. H01L 21/3065; H01J 37/32; H01L 21/311; H01L 21/3213

(52) U.S. Cl. CPC H01L 21/3065; H01J 37/32449; H01L 21/31116; H01L 21/32136; H01J 2237/3341

(57) ABSTRACT

In one exemplary embodiment, an etching method may include (a) providing a substrate, the substrate including a carbon-containing film and a mask on the carbon-containing film; and (b) etching the carbon-containing film with plasma generated from a process gas including an oxygen-containing gas and a sulfur-containing gas, wherein in the (b), a pulse of bias power is supplied to a substrate support supporting the substrate, the pulse is periodically repeated, and a frequency defining a cycle of the pulse is 5 kHz or more.

### CROSS-REFERENCE TO RELATED APPLICATIONS

This application is a continuation application of PCT Application No. PCT/JP2024/002876, filed on Jan. 30, 2024, which claims the benefit of priority from Japanese Patent Application No. 2023-019757, filed on Feb. 13, 2023. The entire contents of the above listed PCT and priority applications are incorporated herein by reference.

### BACKGROUND

### Field

The present disclosure relates to an etching method.

### Description of the Related Art

Japanese Unexamined Patent Application Publication No. 2007-180358 discloses an etching method capable of etching a film while suppressing a profile distortion of a recess

### SUMMARY

Disclosed herein is an etching method. The etching method may include (a) providing a substrate, the substrate including a carbon-containing film and a mask on the carbon-containing film; and (b) etching the carbon-containing film with plasma generated from a process gas including an oxygen-containing gas and a sulfur-containing gas, wherein in the (b), a pulse of bias power is supplied to a substrate support supporting the substrate, the pulse is periodically repeated, and a frequency defining a cycle of the pulse is 5 kHz or more.

### BRIEF DESCRIPTION OF THE DRAWINGS

FIG. 1 is a schematic diagram illustrating a plasma processing apparatus according to an exemplary embodiment.

FIG. 2 is a schematic diagram illustrating a plasma processing apparatus according to an exemplary embodiment.

FIG. 3 is a flowchart illustrating an etching method according to an exemplary embodiment.

FIG. 4 is a cross-sectional view of an example of a substrate to which the method in FIG. 3 may be applied.

FIG. 5 is a cross-sectional view illustrating a step of the etching method according to an exemplary embodiment.

FIG. 6 is an example of a timing chart illustrating a change over time of bias power.

FIG. 7 is a cross-sectional view illustrating a step in an example of the etching method.

FIG. 8 is an example of a timing chart illustrating a change over time of bias power according to a modification example.

FIG. 9 is a view illustrating an example of a planar shape of a bottom of a recess formed by a step of FIG. 5.

FIG. 10 is a view illustrating an example of a planar shape of a bottom of a recess formed by a step of FIG. 7.

FIG. 11 is a graph illustrating an example of a relationship between a depth of a recess and a distortion of a shape of the recess at each depth.

FIG. 12 is a graph illustrating an example of a relationship between a power value of high power of a pulse of bias power and a twisting value.

### DETAILED DESCRIPTION

In the following description, with reference to the drawings, the same reference numbers are assigned to the same components or to similar components having the same function, and overlapping description is omitted.

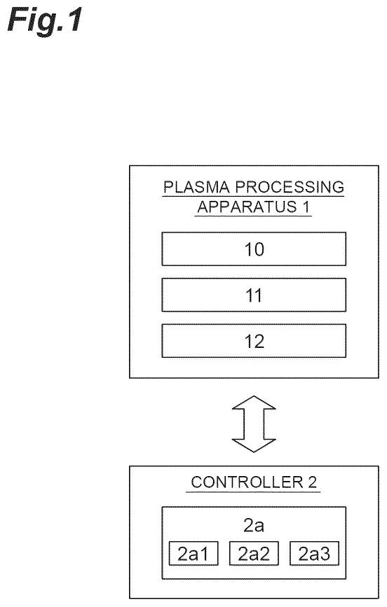

FIG. 1 is a diagram for describing a configuration example of a plasma processing system. In one embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one process gas into the plasma processing space and at least one gas exhaust port for exhausting gases from the plasma processing space. The gas supply port is connected to a gas supply 20 described below and the gas exhaust port is connected to an exhaust system 40 described below. The substrate support 11 is disposed in the plasma processing space and has a substrate support surface for supporting the substrate.

The plasma generator 12 is configured to generate plasma from the at least one process gas supplied into the plasma processing space. The plasma formed in the plasma processing space may be a capacitively coupled plasma (CCP), an inductively coupled plasma (ICP), an electron-cyclotron-resonance (ECR) plasma, a helicon wave plasma (HWP), or a surface wave plasma (SWP), or the like. In addition, various types of plasma generators including an alternating current (AC) plasma generator and a direct current (DC) plasma generator may be used. In one embodiment, an AC signal (AC power) used in the AC plasma generator has a frequency in a range of 100 kHz to 10 GHz. Therefore, the AC signal includes a radio frequency (RF) signal and a microwave signal. In one embodiment, the RF signal has a frequency in a range of 100 kHz to 150 MHz.

The controller 2 processes computer-executable instructions for causing the plasma processing apparatus 1 to execute various steps described in the present disclosure. The controller 2 may be configured to control each element of the plasma processing apparatus 1 to execute various steps described herein. In one embodiment, the controller 2 may be partially or entirely incorporated into the plasma processing apparatus 1. The controller 2 may include a processor 2al, a storage 2a2, and a communication interface 2a3. The controller 2 is realized by, for example, a computer 2a. The processor 2al can be configured to read out a program from the storage 2a2 and execute the read out program to perform various control operations. This program may be stored in the storage 2a2 in advance, or may be acquired via the medium when necessary. The acquired program is stored in the storage 2a2, and is read out from the storage 2a2 and executed by the processor 2al. The medium may be various storage media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or combinations thereof. The communication interface 2a3 may communicate with the plasma processing apparatus 1 via a communication line such as a local area network (LAN).

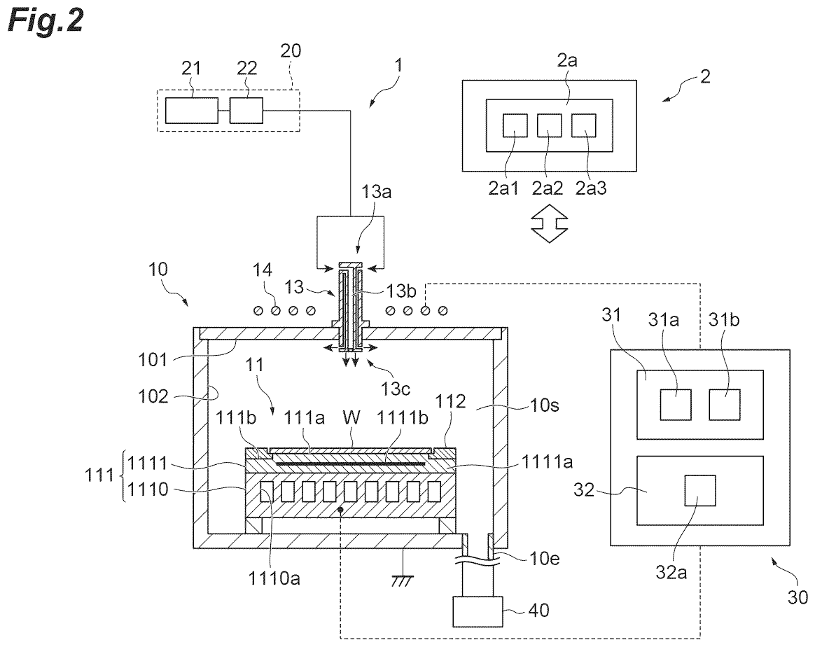

In the following, a configuration example of an inductively coupled plasma processing apparatus, which is an example of the plasma processing apparatus 1, will be described. FIG. 2 is a diagram for describing a configuration example of an inductively coupled plasma processing apparatus.

The inductively coupled plasma processing apparatus 1 includes the plasma processing chamber 10, the gas supply 20, a power supply 30, and an exhaust system 40. The plasma processing chamber 10 includes a dielectric window 101. In addition, the plasma processing apparatus 1 includes a substrate support 11, a gas introduction unit, and an antenna 14. The substrate support 11 is disposed in the plasma processing chamber 10. The antenna 14 is disposed on or above the plasma processing chamber 10 (that is, on or above the dielectric window 101). The plasma processing chamber 10 has a plasma processing space 10s that is defined by the dielectric window 101, a side wall 102 of the plasma processing chamber 10, and the substrate support 11. The plasma processing chamber 10 is grounded.

The substrate support 11 includes a body 111 and a ring assembly 112. The body 111 has a central region 111a for supporting the substrate W and an annular region 111b for supporting the ring assembly 112. A wafer is an example of the substrate W. The annular region 111b of the body 111 surrounds the central region 111a of the body 111 in a plan view. The substrate W is disposed on the central region 111a of the body 111, and the ring assembly 112 is disposed on the annular region 111b of the body 111 to surround the substrate W on the central region 111a of the body 111. Thus, the central region 111a is also referred to as a substrate support surface for supporting the substrate W, while the annular region 111b is also referred to as a ring support surface for supporting the ring assembly 112.

In one embodiment, the body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. In addition, other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to a RF power supply 31 and/or a DC power supply 32 described below may be disposed in the ceramic member 1111a. In this case, at least one RF/DC electrode functions as the bias electrode. The conductive member of the base 1110 and at least one RF/DC electrode may function as a plurality of bias electrodes. In addition, the electrostatic electrode 1111b may function as the bias electrode. Therefore, the substrate support 11 includes at least one bias electrode.

The ring assembly 112 includes one or a plurality of annular members. In one embodiment, the one or plurality of annular members include one or a plurality of edge rings and at least one cover ring. The edge ring is formed of a conductive material or an insulating material, and the cover ring is formed of an insulating material.

In addition, the substrate support 11 may include a temperature adjusting module that is configured to adjust at least one of the electrostatic chuck 1111, the ring assembly 112, and the substrate to a target temperature. The temperature adjusting module may include a heater, a heat transfer medium, a flow path 1110a, or any combination thereof. A heat transfer fluid, such as brine or gas, flows into the flow path 1110a. In one embodiment, the flow path 1110a is formed in the base 1110, and one or a plurality of heaters are disposed in the ceramic member 1111a of the electrostatic chuck 1111. In addition, the substrate support 11 may further include a heat transfer gas supply configured to supply a heat transfer gas to a gap between a back surface of the substrate W and the central region 111a.

The gas introduction unit is configured to introduce at least one process gas from the gas supply 20 into the plasma processing space 10s. In one embodiment, the gas introduction unit includes a center gas injector (CGI) 13. The center gas injector 13 is disposed above the substrate support 11 and is attached to a central opening formed in the dielectric window 101. The center gas injector 13 has at least one gas supply port 13a, at least one gas flow path 13b, and at least one gas introduction port 13c. The process gas supplied to the gas supply port 13a passes through the gas flow path 13b and is introduced into the plasma processing space 10s from the gas introduction port 13c. The gas introduction unit may include one or a plurality of side gas injectors (SGIs) attached to one or a plurality of openings formed in the side wall 102, in addition to or instead of the center gas injector 13.

The gas supply 20 may include at least one gas source 21 and at least one flow rate control device 22. In one embodiment, the gas supply 20 is configured to supply at least one process gas from the respective corresponding gas source 21 through the respective corresponding flow rate control device 22 to the gas introduction unit. Each flow rate control device 22 may include, for example, a mass flow controller or a pressure-controlled flow rate control device. Further, the gas supply 20 may include at least one flow rate modulation device that modulates or pulses the flow rate of the at least one process gas.

The power supply 30 includes an RF power supply 31, which is coupled to the plasma processing chamber 10 via at least one impedance matching circuit. The RF power supply 31 is configured to supply at least one RF signal (RF power) to at least one bias electrode and the antenna 14. As a result, plasma is formed from at least one process gas supplied to the plasma processing space 10s. Therefore, the RF power supply 31 can function as at least a part of the plasma generator 12. In addition, by supplying the bias RF signal (bias RF power) to at least one bias electrode, a bias potential is generated on the substrate W, and ion in the formed plasma can be drawn into the substrate W.

In one embodiment, the RF power supply 31 includes a first RF generator 31a and a second RF generator 31b. The first RF generator 31a is configured to be coupled to the antenna 14 through at least one impedance matching circuit and is configured to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. The generated one or plurality of source RF signals are supplied to the antenna 14.

The second RF generator 31b is configured to be coupled to at least one bias electrode via at least one impedance matching circuit and is configured to generate a bias RF signal. The frequency of the bias RF signal may be the same as or different from the frequency of the source RF signal. In one embodiment, the bias RF signal has a frequency lower than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The generated one or plurality of bias RF signals are supplied to at least one bias electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a bias DC generator 32a. In one embodiment, the bias DC generator 32a is configured to be connected to at least one bias electrode and is configured to generate a bias DC signal. The generated bias DC signal is applied to at least one bias electrode.

In various embodiments, the bias DC signal may be pulsed. In this case, a sequence of the voltage pulses is applied to at least one bias electrode. The voltage pulse may have a pulse waveform of a rectangular, trapezoidal, triangular, or a combination thereof. In one embodiment, a waveform generator for generating the sequence of voltage pulses from the DC signal is connected between the bias DC generator 32a and at least one bias electrode. Therefore, the bias DC generator 32a and the waveform generator constitute a voltage pulse generator. The voltage pulse may have a positive polarity or may have a negative polarity. Further, the sequence of the voltage pulses may include one or a plurality of positive-polarity voltage pulses and one or a plurality of negative-polarity voltage pulses in one cycle. The bias DC generator 32a may be provided in addition to the RF power supply 31, or may be provided instead of the second RF generator 31b.

The antenna 14 includes one or a plurality of coils. In one embodiment, the antenna 14 may include an outer coil and an inner coil disposed coaxially. In this case, the RF power supply 31 may be connected to both the outer coil and the inner coil, or may be connected to either the outer coil or the inner coil. In the former case, the same RF generator may be connected to both the outer coil and the inner coil, or separate RF generators may be separately connected to the outer coil and the inner coil.

The exhaust system 40 may be connected to, for example, a gas exhaust port 10e provided in a bottom of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

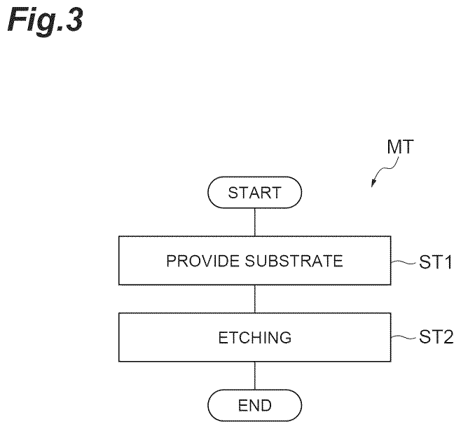

FIG. 3 is a flowchart illustrating an etching method according to an exemplary embodiment. The etching method MT illustrated in FIG. 3 (hereinafter, referred to as “method MT”) may be performed by a plasma processing apparatus 1 of the above-described embodiment. The method MT may be applied to a substrate W.

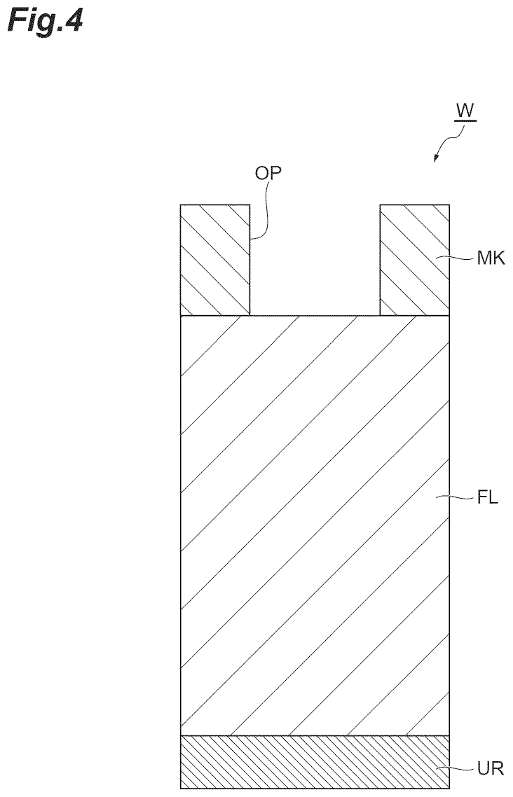

FIG. 4 is a cross-sectional view of an example of the substrate W to which the method in FIG. 3 may be applied. As illustrated in FIG. 4, in one embodiment, the substrate W includes a carbon-containing film FL and a mask MK on the carbon-containing film FL. The substrate W may further include an underlying region UR under the carbon-containing film FL.

The carbon-containing film FL may include an amorphous carbon film. The carbon-containing film FL may have a thickness of 2,000 nm or more or may have a thickness of 3,000 nm or more. The carbon-containing film FL may have a thickness of 5,000 nm or less.

The mask MK may have an opening OP. The mask MK may have a plurality of openings OP. The opening OP may have a hole pattern or a line pattern. A dimension (Critical Dimension: CD) of the opening OP may be 100 nm or less. The mask MK may include a silicon-containing film. The mask MK may include at least one of a silicon oxynitride film (SiON), a silicon oxide film (SiO₂), a silicon nitride film (SiNₓ), and a tungsten silicide (WₓSi_{y}) film.

The underlying region UR may include a silicon-containing film. The underlying region UR may include, for example, at least one film for a memory device such as DRAM or 3D-NAND.

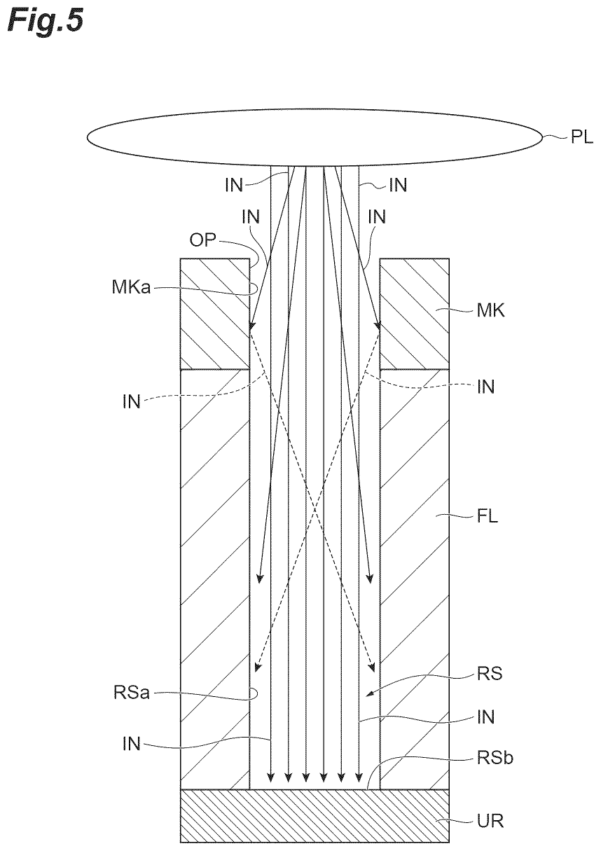

In the following, the method MT will be described with reference to FIGS. 3 to 6 by using, as an example, the case where the method MT is applied to the substrate W by using the plasma processing apparatus 1 in the above-described embodiment. FIG. 5 is a cross-sectional view illustrating a step of the etching method according to an exemplary embodiment. In a case where the plasma processing apparatus 1 is used, the method MT can be performed in the plasma processing apparatus 1 in a manner that the controller 2 controls each unit of the plasma processing apparatus 1. In the method MT, as illustrated in FIG. 2, the substrate W on a substrate support 11 disposed in a plasma processing chamber 10 is processed.

As illustrated in FIG. 3, the method MT includes Step ST1 and Step ST2. Step ST1 and Step ST2 may be executed in order.

### (Step ST1)

In Step ST1, the substrate W illustrated in FIG. 4 is provided. The substrate W may be disposed in the plasma processing chamber 10. The substrate W may be supported by the substrate support 11 in the plasma processing chamber 10. The underlying region UR can be disposed between the substrate support 11 and the carbon-containing film FL.

### (Step ST2)

In Step ST2, as illustrated in FIG. 5, the carbon-containing film FL is etched through the opening OP using the plasma PL generated from the process gas. A recess RS is formed in the carbon-containing film FL by etching. The recess RS has a side wall RSa and a bottom RSb. The bottom RSb may reach the underlying region UR. An aspect ratio of the recess RS may be 20 or more, or 30 or more. An aspect ratio of the recess RS may be 50 or less. The aspect ratio of the recess RS is a ratio of the depth of the recess RS to the dimension (CD) of the recess RS. The process gas includes an oxygen-containing gas and a sulfur-containing gas. Examples of the oxygen-containing gas include oxygen gas. Examples of the sulfur-containing gas include carbonyl sulfide (COS) gas. The process gas may include an inert gas. Examples of the inert gas include argon gas. A temperature of the substrate support 11 in Step ST2 may be 0° C. or lower, or may be −40° C. or lower. The temperature of the substrate support 11 in Step ST2 may be 80° C. or lower. In a case where the temperature of the substrate support 11 is lowered, the etching rate of the carbon-containing film FL can be increased, and the profile distortion (bowing) of the side wall RSa of the recess RS can be suppressed.

FIG. 5 illustrates an example of a trajectory of the ion IN generated in the plasma PL. The ion IN is, for example, an argon ion (Ar⁺) generated by dissociation of argon gas in the plasma. By supplying the bias power to at least one bias electrode, a bias potential is generated on the substrate W. As a result, the ion IN in the plasma PL is drawn into the substrate W. The ion IN travels toward the bottom RSb of the recess RS. The trajectory of the ion IN from the plasma PL toward the substrate W is indicated by a solid line. The ion assist reaction is promoted by the ion IN being incident on the bottom RSb. The ion assist reaction is a phenomenon in which incident ions IN promote a surface reaction. The ion IN may be incident on the substrate W at an angle. In that case, the ion IN collides with a side wall MKa of the mask MK, and the reflected ion IN (indicated by a dotted line) can be incident on the recess RS.

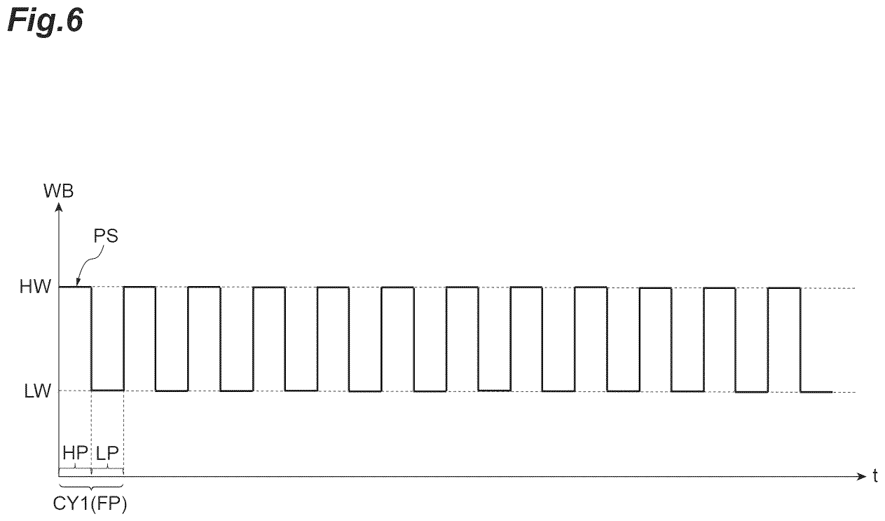

FIG. 6 is an example of a timing chart illustrating a change over time of bias power. In FIG. 6, a vertical axis indicates a power value of the bias power WB, and a horizontal axis indicates time t. This timing chart is related to Step ST2. As illustrated in FIG. 6, in Step ST2, a pulse PS of the bias power WB is supplied to the substrate support 11. The pulse PS of the bias power WB may be radio frequency power applied to the bias electrode in the body 111 of the substrate support 11. The pulse PS of the bias power WB is periodically repeated in a cycle CY1. The cycle CY1 may include a high power period HP and a low power period LP. The low power period LP is a period after the high power period HP. In the high power period HP, the pulse PS of the bias power WB may be maintained at high power HW. In the low power period LP, the pulse PS of the bias power WB can be maintained at low power LW. The low power LW may be a power value lower than the high power HW, or may be in a state where the bias power WB is turned off (0 W).

A frequency FP defining the cycle CY1 of the pulse PS is 5 kHz or more. The frequency FP may be 15 kHz or more. The frequency FP may be 25 kHz or less or 15 kHz or less. A duty ratio of the pulse PS may be 30% or more, 60% or less, or 50% or less. The duty ratio of the pulse PS may be 90% or less. The duty ratio of the pulse PS is a ratio of the high power period HP to the cycle CY1. A level of the pulse PS (the power value of the high power HW) may be 2,000 W or more, 6,000 W or less, or 5,000 W or less.

In Step ST2, the plasma PL may be generated by supplying the source power. The source power may be radio frequency power applied to the antenna 14 in FIG. 2. The frequency of the source power has a frequency higher than a frequency of the bias power WB. In Step ST2, a continuous wave (CW) of the source power may be supplied, or a pulse of the source power may be supplied. In a case where the pulse of the power is supplied, the pulse may be generated by switching the power on and off, or the pulse may be generated by varying the power levels. In a case where the pulse of the source power is supplied in Step ST2, a profile distortion (bowing) of the side wall RSa of the recess RS can be suppressed.

According to the plasma processing apparatus 1 and the method MT described above, the recess RS is formed in the carbon-containing film FL by etching in Step ST2. The profile distortion of the recess RS can be suppressed as compared with a case where the frequency FP of the pulse PS of the bias power WB supplied to the substrate support 11 in Step ST2 is lower than 5 kHz. For example, the profile distortion (bowing) of the side wall RSa of the recess RS can be suppressed. For example, distortion of a planar shape of the bottom RSb of the recess RS can be suppressed. One mechanism by which the profile distortion of the recess RS is suppressed can be presumed as follows, but the present disclosure is not limited thereto. In a case where the frequency FP of the pulse PS of the bias power WB is 5 kHz or more, charging of the mask MK due to the collision of the ions IN in the plasma PL with the mask MK is suppressed. As a result, the trajectory of the ion IN in the plasma PL is less likely to be bent. Therefore, it is possible to suppress the ion IN from colliding with the side wall RSa of the recess RS and etching the side wall RSa. Furthermore, it is possible to suppress the ion IN from colliding with the mask MK and etching the mask MK.

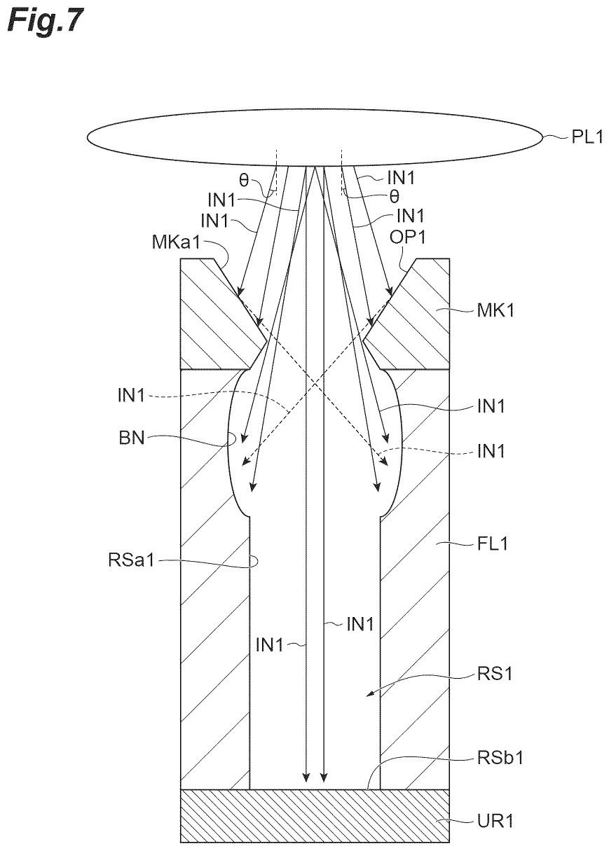

Another mechanism by which the profile distortion of the recess RS is suppressed can be presumed as follows, but the present disclosure is not limited thereto. The assumed mechanism will be described with reference to FIG. 7.

FIG. 7 is a cross-sectional view illustrating a step in an example of the etching method. FIG. 7 illustrates a step performed in the same manner as in Step ST2 of FIG. 5 except that the frequency FP of the pulse PS of the bias power WB is less than 5 kHz. In FIG. 7, the carbon-containing film FL1 is etched through the opening OP1 by the plasma PL1 generated from the process gas. A recess RS1 is formed in the carbon-containing film FL1 by etching. In FIG. 7, the number of ions IN1 in which an angle θ between a direction orthogonal to the main surface of the substrate W1 and a traveling direction of the ions IN1 is increased as compared with that in FIG. 5. This is presumed to be because the electrons are likely to remain in the opening OP1 of the mask MK1 since the frequency FP of the pulse PS is low. By the collision between the remained electron and the ion IN1, the trajectory of the ion IN1 is bent, and the traveling direction of many ions IN1 is directed laterally.

As the traveling directions of a large number of ions IN1 are directed laterally, the number of ions IN1 that collide with the side wall MKa1 of the mask MK1 increases, and the side wall MKa1 of the mask MK1 is easily etched. Accordingly, the side wall MKa1 may have a shape inclined toward the bottom RSb1 such that the dimensions of the opening OP1 are reduced from an upper end to a lower end of the opening OP1. As a result, the ion IN1 that has collided with and reflected from the side wall MKa1 is likely to collide with the upper portion of the side wall RSa1 of the recess RS1. Accordingly, it is assumed that the bowing BN is likely to be generated in the upper portion of the side wall RSa1. Furthermore, since the traveling direction of the ion IN1 is directed laterally, the number of ions IN1 that are incident perpendicularly toward the bottom RSb1 is reduced. Therefore, the distortion of a planar shape of the recess RS1 in the cross section orthogonal to a depth direction of the recess RS1 increases.

In a case where the duty ratio of the pulse PS is 50% or less, a period during which the chemical species in the recess RS formed by etching are exhausted becomes longer. Therefore, the opening of the recess RS is suppressed from being blocked by the deposit formed by the chemical species in the recess RS.

In a case where the carbon-containing film FL has a thickness of 2,000 nm or more, the distortion of the planar shape of the bottom RSb of the recess RS can be further suppressed.

In a case where the power value of the high power HW of the pulse PS is 2,000 W or more and 5,000 W or less, the distortion of the planar shape of the bottom RSb of the recess RS can be suppressed. The decrease in the etching selectivity of the carbon-containing film FL with respect to the mask MK can be suppressed.

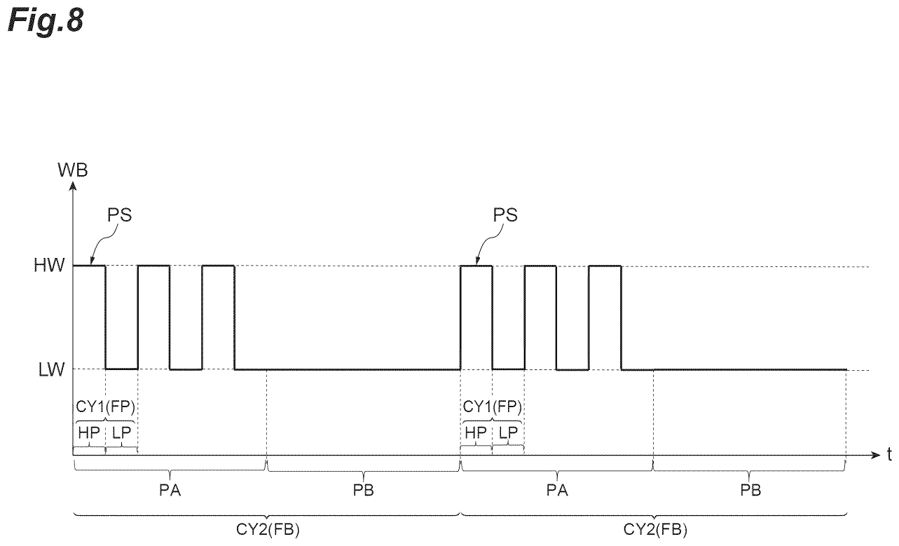

FIG. 8 is an example of a timing chart illustrating a change over time of bias power WB according to a modification example. As illustrated in FIG. 8, Step ST2 may include a first period PA and a second period PB. The second period PB is a period after the first period PA. The first period PA and the second period PB may be alternately and periodically repeated with a cycle CY2. In the first period PA, the pulse PS described in FIG. 6 may be supplied. In the first period PA, the pulse PS of the high power HW (first level) may be supplied. In the second period PB, the bias power WB may not be supplied to the substrate support 11. Alternatively, in the second period PB, the bias power WB of the low power LW (second level) having a power value lower than a power value of the high power HW may be supplied to the substrate support 11. In the second period PB, the bias power WB may be maintained at the low power LW. The power value of the low power LW may be a power value lower than the power value of the high power HW as in FIG. 6, or may be a state (0 W) in which the bias power WB is turned off.

In a case where Step ST2 includes the first period PA and the second period PB, the chemical species in the recess RS formed by etching in the first period PA are exhausted in the second period PB. Therefore, it is possible to suppress the blockage of the opening of the recess RS by the deposits formed by the chemical species in the recess RS, as compared with a case where the second period PB is not present. Furthermore, by suppressing the blockage, the ion IN is likely to enter the recess RS, and the etching is promoted. Therefore, as compared with a case where the second period PB is not present, it is possible to improve the etching selectivity of the carbon-containing film FL with respect to the mask MK.

A second frequency (frequency FB) that defines the cycle CY2 of the first period PA and the second period PB may be 100 Hz or more and 1 kHz or less. In a case where the frequency FB is 100 Hz or more, the first period PA in which the deposit can be formed in the opening of the recess RS can be shortened. On the other hand, in a case where the frequency FB is 1 kHz or less, the second period PB, which is a period in which the chemical species in the recess RS can be exhausted, can be lengthened. Therefore, in a case where the second frequency is 100 Hz or more and 1 kHz or less, it is possible to further suppress the blockage of the opening of the recess RS by the deposits. The frequency FB may be 500 Hz or more. The frequency FB may be 500 Hz or less.

Various experiments performed for evaluating the method MT are described below. The experiments described below do not limit the present disclosure.

### (First Experiment)

In the first experiment, a substrate having an amorphous carbon film and a mask on the amorphous carbon film is prepared. A thickness of the amorphous carbon film is 3,500 nm. The mask is a SiON film having a circular opening. With regard to this substrate, the amorphous carbon film is etched with plasma generated from the process gas to form a recess. A planar shape of the recess is ideally circular. The process gas includes an oxygen gas, a COS gas, and an argon gas. During the etching, a pulse of bias power is supplied to the substrate support. The pulse is periodically repeated. The frequency that defines the cycle of the pulse is 10 kHz. The high power value of the pulse of the bias power is 3,500 W. The low power value of the pulse of the bias power is 0 W. The duty ratio of the pulse of the bias power is 30%.

### (Second Experiment)

The second experiment is performed in the same manner as in the first experiment, except that the frequency that defines the cycle of the pulse of the bias power is set to 1 kHz instead of 10 kHz.

### (Third Experiment)

The third experiment is performed in the same manner as in the first experiment, except that the frequency that defines the cycle of the pulse of the bias power is set to 300 Hz instead of 10 kHz.

### (First Experimental Results)

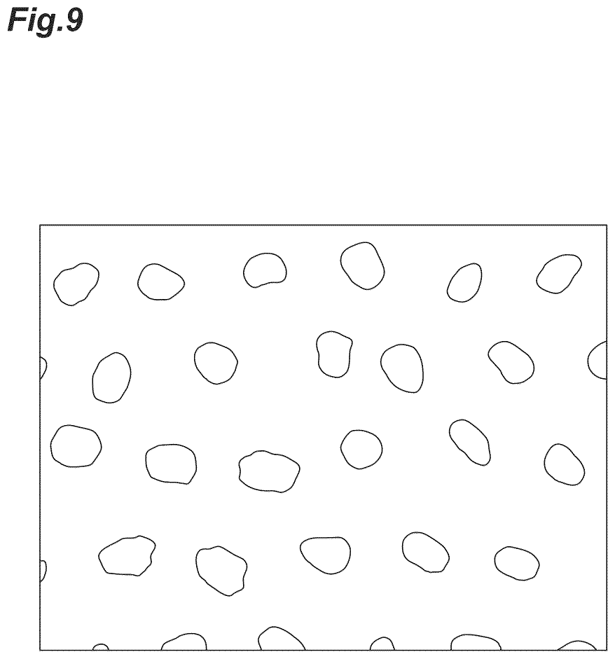

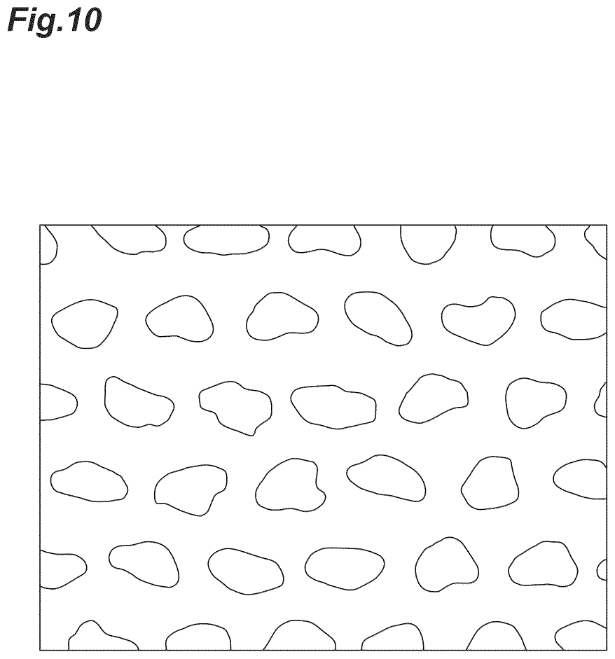

In the first experiment to the third experiment, the distortion of the recess formed in the amorphous carbon film in a planar shape is measured according to a depth of the recess. FIG. 9 is a view illustrating an example of a planar shape of the bottom of the recess formed by Step ST2 of FIG. 5. FIG. 9 illustrates experimental results of the first experiment (frequency of pulse: 10 kHz). FIG. 10 is a view illustrating an example of a planar shape of the bottom of the recess formed by a step of FIG. 7. FIG. 10 illustrates experimental results of the third experiment (frequency of pulse: 300 Hz). The planar shape at the bottom illustrated in FIG. 9 has a smaller distortion than the planar shape at the bottom illustrated in FIG. 10. In other words, in a case where an ideal planar shape of the bottom is a circle, the planar shape of the bottom is close to a perfect circle as the frequency of the pulse is higher.

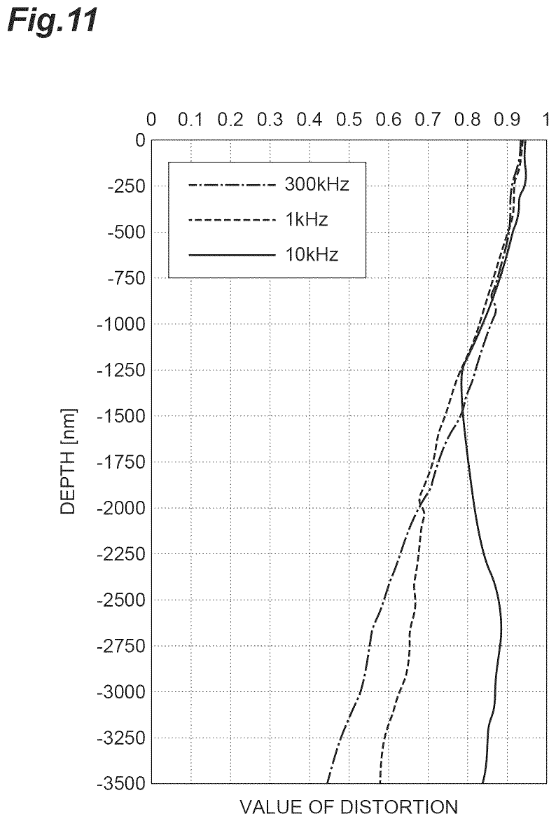

FIG. 11 is a graph illustrating an example of a relationship between a depth of a recess and a distortion of a planar shape of the recess at each depth. A vertical axis of the graph indicates the depth of the recess. A horizontal axis of the graph indicates a value of the distortion of the planar shape of the recess. The value of the distortion of the planar shape of the recess is measured by terminal PC offline length measurement software manufactured by Hitachi, Ltd. The closer the value of the distortion is to 1, the smaller the distortion is. In a case where the ideal planar shape of the recess is a circle, the closer the value of the distortion is to 1, the closer the planar shape of the recess is to a perfect circle. In other words, in a case where the ideal planar shape of the recess is a circle, the closer the value of the distortion is to 1, the higher the roundness of the planar shape of the recess is. As can be seen from FIG. 11, a difference due to the frequency of the pulse is remarkably observed from the vicinity of the depth of 1,250 nm of the recess. In a case where the frequency of the pulse is 10 kHz, the decrease in the value of the distortion is suppressed from the vicinity of 1,250 nm to 3,500 nm in the depth of the recess. As the frequency of the pulse decreases, the value of the distortion decreases from the vicinity of the depth of 1,250 nm to 3,500 nm of the recess. Therefore, the value of the distortion at the bottom (the vicinity of a depth of 3,500 nm) of the recess is the largest in a case where the frequency is 10 kHz. From the results of FIG. 11, it can be seen that, in a case where the frequency of the pulse is 10 kHz, even in a case where the depth of the recess is deep, the value of the distortion can be maintained to be large (the distortion can be maintained to be small).

Furthermore, in each of the first experiment to the third experiment, the degree of bowing occurring in the upper portion of the side wall of the recess is confirmed. As a result, it is confirmed that the bowing can be suppressed in a case where the frequency of the pulse is 10 kHz, as compared with a case where the frequency is 300 Hz and 1 kHz. In addition, in each of the first experiment to the third experiment, the shape of the mask after etching is confirmed. It is confirmed that in a case where the frequency of the pulse is 10 kHz, the deformation of the mask (refer to FIG. 7) can be suppressed as compared with a case where the frequency is 300 Hz and a case where the frequency is 1 kHz. It is found that a decrease in the etching selectivity of the amorphous carbon film with respect to the mask can be suppressed.

From the above, it is found that, in a case where the frequency of the pulse is 5 kHz or more, the profile distortion of the recess (distortion of the planar shape of the bottom of the recess and bowing occurring at the upper portion of the side wall of the recess) can be suppressed.

### (Fourth Experiment)

The fourth experiment is performed in the same manner as in the first experiment, except that the power value of the high power of the pulse of the bias power is set to 2,000 W instead of 3,500 W.

### (Fifth Experiment)

The fifth experiment is performed in the same manner as in the first experiment, except that the power value of the high power of the pulse of the bias power is set to 5,000 W instead of 3,500 W.

### (Sixth Experiment)

The sixth experiment is performed in the same manner as in the first experiment, except that the power value of the high power of the pulse of the bias power is set to 6,000 W instead of 3,500 W.

### (Seventh Experiment)

The seventh experiment is performed in the same manner as in the first experiment, except that the power value of the high power of the pulse of the bias power is set to 3,000 W instead of 3,500 W.

### (Second Experimental Results)

In each of the first experiment and the fourth experiment to sixth experiment, a value of the distortion of the planar shape of the bottom of the recess is measured. As a result, it is found that the distortion increases as the power value of the pulse having high power increases. In addition, the etching selectivity of the amorphous carbon film with respect to the mask is calculated by measuring a thickness of the mask. As a result, it is found that the etching selectivity decreases as the power value of the pulse having high power increases. It is assumed that there is a correlation between an increase in distortion and a decrease in the etching selectivity as follows. The mask is deformed as the etching selectivity ratio decreases. Therefore, ions that collide with the side wall of the mask and are directed laterally increase, and the ions hardly reach the bottom. As a result, the distortion of the planar shape of the bottom of the recess increases.

### (Third Experimental Results)

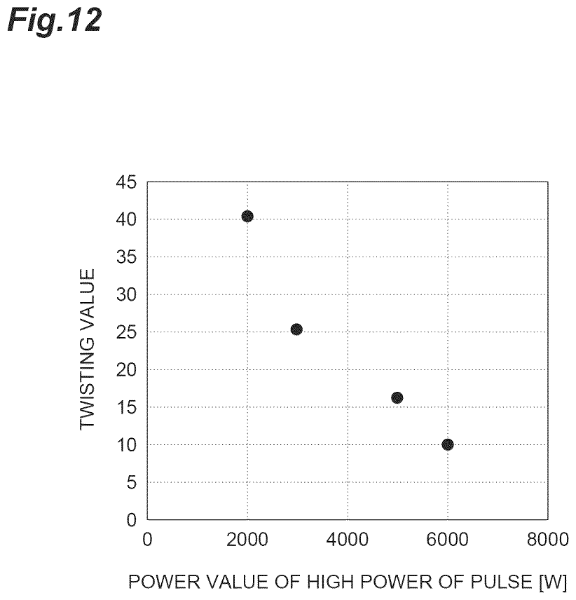

In each of the fourth experiment to the seventh experiment, a value (hereinafter, referred to as a twisting value) obtained by quantifying the twisting of the recess is measured. FIG. 12 is a graph illustrating an example of a relationship between the power value of the high power of the pulse of the bias power and the twisting value.

Twisting refers to twisting from an upper end of the side wall of the recess to the bottom. The twisting value is a value obtained by quantifying an amount of deviation of the center of the bottom of the recess from the central axis in a case where the central axis of the recess is set in the cross section (refer to FIG. 5) of the recess. As a result of the measurement, it is found that as the power value of the pulse having high power increases, the twisting value decreases (the twisting is suppressed) as illustrated in FIG. 12.

### (Eighth Experiment)

The eighth experiment is performed in the same manner as in the first experiment, except that the duty ratio of the pulse of the bias power is set to 40% instead of 30%.

### (Ninth Experiment)

The ninth experiment is performed in the same manner as in the first experiment, except that the duty ratio of the pulse of the bias power is set to 60% instead of 30%.

### (Fourth Experimental Results)

In each of the first experiment, the eighth experiment, and the ninth experiment, the value of the distortion of the planar shape of the bottom of the recess and the twisting value are measured. As a result, it is found that there is no significant difference in the value of distortion even in a case where the duty ratio of the pulse is changed. On the other hand, it is found that the twisting value decreases as the duty ratio of the pulse increases.

Furthermore, in each of the first experiment, the eighth experiment, and the ninth experiment, the amount of the deposit blocking the opening of the recess is confirmed. As a result, it is found that as the duty ratio of the pulse increases, the amount of deposit increases, and the opening of the recess is more likely to be blocked. As the duty ratio of the pulse increases, the length of the low power period is shortened. In a case where the length of the low power period is shortened, an exhaust period, which is a period in which the chemical species are exhausted, is shortened, and it is assumed that the deposits are likely to be deposited. The chemical species include ions, radicals, and the like.

In the tenth experiment to the twelfth experiment described below, a supply mode different from the supply mode of the bias power in the first experiment to the ninth experiment is used.

### (Tenth Experiment)

The supply mode of the bias power is used in a modification example described in FIG. 8. The frequency FB that defines the cycle CY2 of the first period PA and the second period PB is 100 Hz. A duty ratio, which is a ratio of the first period to the cycle, is 50%. The frequency of the pulse of the bias power is 10 kHz. The power value of the high power of the pulse is 3,500 W. The duty ratio of the pulse of the bias power is 60%. With regard to other conditions, the tenth experiment is performed in the same manner as in the ninth experiment.

### (Eleventh Experiment)

The eleventh experiment is performed in the same manner as in the tenth experiment, except that the frequency FB is set to 500 Hz instead of 100 Hz.

### (Twelfth Experiment)

The twelfth experiment is performed in the same manner as in the tenth experiment, except that the frequency FB is set to 1 kHz instead of 100 Hz.

### (Fifth Experimental Results)

In each of the ninth experiment to the twelfth experiment, the amount of the deposit that can block the opening of the recess is confirmed. As a result, it is confirmed that the amount of deposit is reduced in the tenth experiment to the twelfth experiment as compared with the ninth experiment. In the tenth experiment to the twelfth experiment, since the length of the exhaust period is longer than that in the eighth experiment because the second period is provided, it is assumed that the deposit is less likely to be deposited. In the tenth experiment to the twelfth experiment, it is confirmed that the amount of deposit is the lowest in the eleventh experiment. In a case where the frequency FB is 500 Hz, the cycle is shorter than in a case where the frequency FB is 100 Hz, and thus the first period in one cycle is short. Therefore, it is assumed that the deposit is less likely to be deposited. In a case where the frequency FB is 500 Hz, the cycle is longer than in a case where the frequency FB is 1 kHz, and thus the second period in one cycle is long. Therefore, it is assumed that the exhaust time is likely to be secured and the deposit is less likely to be deposited.

Furthermore, in each of the ninth experiment to the twelfth experiment, the value of the distortion of the planar shape of the bottom of the recess and the twisting value are measured. In the ninth experiment to the twelfth experiment, it is found that there is no significant difference in the value of distortion and the twisting value. Therefore, it is found that there is no significant difference in the value of distortion and the twisting value even in a case where the supply mode of the bias power is changed.

Here, the various exemplary embodiments included in the present disclosure are described in [E1] to [E11] below.

[E1] An etching method including: (a) providing a substrate, the substrate including a carbon-containing film and a mask on the carbon-containing film; and (b) etching the carbon-containing film with plasma generated from a process gas including an oxygen-containing gas and a sulfur-containing gas, in which in the (b), a pulse of bias power is supplied to a substrate support supporting the substrate, the pulse is periodically repeated, and a frequency defining a cycle of the pulse is 5 kHz or more.

[E2] The etching method according to [E1], in which the (b) includes a first period and a second period after the first period, in the first period, the pulse at a first level is supplied, and in the second period, bias power is not supplied to the substrate support, or bias power at a second level lower than the first level is supplied to the substrate support.

[E3] The etching method according to [E2], in which the frequency is a first frequency, the first period and the second period are alternately and periodically repeated, and a second frequency defining a cycle of the first period and the second period is 100 Hz or more and 1 kHz or less.

[E4] The etching method according to any one of [E1] to [E3], in which a duty ratio of the pulse is 50% or less.

[E5] The etching method according to any one of [E1] to [E4], in which in the (b), a continuous wave of radio frequency power for generating the plasma is supplied.

[E6] The etching method according to any one of [E1] to [E5], in which the carbon-containing film has a thickness of 2000 nm or more.

[E7] The etching method according to any one of [E1] to [E6], in which a recess formed in the carbon-containing film by the etching in the (b) has an aspect ratio of 20 or more.

[E8] The etching method according to any one of [E1] to [E7], in which the mask includes a silicon-containing film.

[E9] The etching method according to any one of [E1] to [E8], in which the process gas further includes an inert gas.

[E10] The etching method according to any one of [E1] to [E9], in which a level of the pulse is 2000 W or more and 5000 W or less.

[E11] A plasma processing apparatus including: a chamber, a substrate support configured to support a substrate in the chamber, the substrate including a carbon-containing film and a mask on the carbon-containing film, a gas supply configured to supply a process gas including an oxygen-containing gas and a sulfur-containing gas into the chamber, a plasma generator configured to generate plasma from the process gas in the chamber, a power supply configured to supply bias power to the substrate support, and circuitry configured to control the gas supply, the plasma generator, and the power supply to etch the carbon-containing film with the plasma while supplying a pulse of the bias power to the substrate support, wherein a frequency defining a cycle of the pulse is 5 kHz or more.

It is to be understood that not all aspects, advantages and features described herein may necessarily be achieved by, or included in, any one particular example. Indeed, having described and illustrated various examples herein, it should be apparent that other examples may be modified in arrangement and detail.

What is claimed is:

1. An etching method comprising:
(a) providing a substrate, the substrate including a carbon-containing film and a mask on the carbon-containing film; and
(b) etching the carbon-containing film with plasma generated from a process gas including an oxygen-containing gas and a sulfur-containing gas,
wherein in the (b), a pulse of bias power is supplied to a substrate support supporting the substrate, the pulse is periodically repeated, and
a frequency defining a cycle of the pulse is 5 kHz or more.

2. The etching method according to claim 1,
wherein the (b) includes a first period and a second period after the first period,
in the first period, the pulse at a first level is supplied, and
in the second period, bias power is not supplied to the substrate support, or bias power at a second level lower than the first level is supplied to the substrate support.

3. The etching method according to claim 2,
wherein the frequency of the pulse is a first frequency,
the first period and the second period are alternately and periodically repeated, and
a second frequency defining a cycle of the first period and the second period is 100 Hz or more and 1 kHz or less.

4. The etching method according to claim 1,
wherein a duty ratio of the pulse is 50% or less.

5. The etching method according to claim 1,
wherein in the (b), a continuous wave of radio frequency power for generating the plasma is supplied.

6. The etching method according to claim 1,
wherein the carbon-containing film has a thickness of 2000 nm or more.

7. The etching method according to claim 1,
wherein a recess formed in the carbon-containing film by the etching in the (b) has an aspect ratio of 20 or more.

8. The etching method according to claim 1,
wherein the mask includes a silicon-containing film.

9. The etching method according to claim 1,
wherein the process gas further includes an inert gas.

10. The etching method according to claim 1,
wherein a level of the pulse is 2000 W or more and 5000 W or less.

11. A plasma processing apparatus comprising:
a chamber;
a substrate support configured to support a substrate in the chamber, the substrate including a carbon-containing film and a mask on the carbon-containing film;
a gas supply configured to supply a process gas including an oxygen-containing gas and a sulfur-containing gas into the chamber,
a plasma generator configured to generate plasma from the process gas in the chamber;
a power supply configured to supply bias power to the substrate support; and
circuitry configured to control the gas supply, the plasma generator, and the power supply to etch the carbon-containing film with the plasma while supplying a pulse of the bias power to the substrate support, wherein a frequency defining a cycle of the pulse is 5 kHz or more.
